(19) United States
(12) Patent Application Publication
(10) Pub. No.: US 2024/0055257 A1
(43) Pub. Date: Feb. 15, 2024

(54) METHOD FOR MANUFACTURING A CONTACT ON A SILICON CARBIDE SUBSTRATE, AND SILICON CARBIDE SEMICONDUCTOR DEVICE

(71) Applicant: Infineon Technologies AG, Neubiberg (DE)

(72) Inventors: Saurabh Roy, Villach (AT); Werner Schustereder, Villach (AT); Ravi Keshav Joshi, Klagenfurt am Wörthersee (AT); Hans-Joachim Schulze, Taufkirchen (DE); Daria Krasnozhon, Villach (AT)

(21) Appl. No.: 18/360,459

(22) Filed: Jul. 27, 2023

(30) Foreign Application Priority Data
Aug. 9, 2022 (DE) 102022208301.6
Jul. 7, 2023 (DE) 10223206489.8

(51) Int. Cl. H01L 21/04; H01L 29/45; H01L 29/16; H01L 29/04

(52) U.S. Cl. CPC H01L 21/0485; H01L 29/452; H01L 29/1608; H01L 29/045

(57) ABSTRACT

The disclosure relates to a method for manufacturing a contact on a SiC substrate, wherein the method includes: providing a crystalline SiC substrate; modifying a crystal structure in a surface area of the SiC substrate such that a carbon-enriched SiC portion is generated in the surface area; forming a contact layer on the SiC substrate by depositing a metallic contact material onto the surface area that includes the carbon-enriched SiC portion; and thermal annealing of at least a part of the carbon-enriched SiC portion of the SiC substrate and at least a part of the contact layer, such that a ternary metallic phase portion including at least the metallic contact material, silicon, and carbon is generated. Furthermore, SiC semiconductor devices are described, which include a crystalline SiC substrate and a contact layer including a ternary metallic phase portion directly in contact with the SiC substrate surface.

### TECHNICAL FIELD

The present disclosure generally relates to methods of manufacturing a contact on a silicon carbide substrate, and a silicon carbide semiconductor device with an Ohmic contact which, among others, is obtainable by the herein described methods.

### BACKGROUND

Semiconductor devices based on wide bandgap semiconductors, such as silicon carbide (SiC) based diodes or power MOSFETs, are considered as the next generation electronic devices, for example in applications in harsh environments or in the power electronics area. In the development of such semiconductor devices, one aspect is the creation of Ohmic contacts between the semiconductor material and the metal contact or metal layer stack above the semiconductor substrate surface. Especially, the creation of good, reproducible, and homogeneous backside Ohmic contacts for the SiC substrates which are extensively used across the industries is a critical topic.

In the light of the above, there is a need of providing SiC based semiconductor devices having reliable and robust Ohmic contacts, especially at the backside of the semiconductor substrate, and providing methods offering a large process window.

### SUMMARY

Some embodiments relate to a method for manufacturing a contact on a silicon carbide substrate, wherein the method may comprise providing a crystalline silicon carbide substrate, modifying a crystal structure in a surface area of the silicon carbide substrate and thereby generating a carbon-enriched silicon carbide portion in the surface area, forming a contact layer on the silicon carbide substrate by depositing a metallic contact material onto the surface area comprising the carbon enriched silicon carbide portion, and thermal annealing of at least a part of the carbon-enriched silicon carbide portion of the silicon carbide substrate and at least a part of the contact layer, thereby generating a ternary metallic phase portion comprising at least the metallic contact material, silicon, and carbon.

The crystalline silicon carbide substrate may be a monocrystalline substrate. For example, hexagonal polytypes, such as 4H—SiC and/or 6H—SiC crystalline polytypes, may be used. However, the substrate may also comprise regions of a different polytype, e.g. 3C—SiC. In the following description, 4H—SiC is used for explaining the technical effects of the embodiments, while it shall not exclude other polytypes, especially other hexagonal monocrystalline polytypes of SiC.

The method as described herein may allow to manufacture a good and reliable Ohmic contact on a SiC substrate for example, a crystalline 4H—SiC substrate. Therefore, the method usually starts with providing such a crystalline substrate which may optionally have device structures at the front side thereof. Different typical wafer processing steps may be carried out before the backside is provided with an Ohmic contact. The method described herein can also be used to prepare a contact on the frontside of a semiconductor substrate. Method steps described in the context of the backside may thus also apply to the frontside.

In this specification, if a first element (e.g. contact or layer or region) is provided “on” a second element (e.g. contact or layer or region) this does not exclude a further element (e.g. an intervening layer or element) being provided between the first element and the second element. In contrast, when a first element is referred to as being “directly on” or extending “directly onto” a second element, there is no further element present.

Once a silicon carbide substrate has been prepared for being contacted, the crystal structure in the surface area of the silicon carbide substrate is modified. More particularly, the surface at which the contact shall be prepared is modified such that a carbon-enriched silicon carbide portion is generated. Any process for increasing the content of carbon may be used for generating the carbon-enriched portion. This portion may extend in the whole surface area. In some embodiments, the carbon-enriched area may be generated in specific areas of the substrate surface, for example, in a regularly patterned manner.

A contact layer may be directly formed on this carbon-enriched silicon carbide portion by depositing a contact material layer on the silicon carbide substrate. The depositing of the contact material can be carried out by any deposition process typically used in semiconductor preparation processes and may depend on the contact material.

The method further may comprise annealing of at least a part of the carbon-enriched silicon carbide portion of the silicon carbide substrate and at least a part of the contact layer. The respective parts of the two layers may, for example, be near to the interface of the layers to enable the creation of a mixed structure comprising elements of the two layers. More particularly, a ternary metallic phase portion is formed comprising at least the metallic contact material, silicon, and carbon. Therefore, the method as described herein utilizes the presence of carbon in the enriched-carbon portion of the silicon carbide substrate to create a highly ordered, textured metallic mixed phase layer, which may be responsible for a low contact resistance. The, thus, formed ternary metallic phase portion at the interface between the silicon carbide substrate and the contact layer provides a good Ohmic contact. With the proper choice of the metal, it is possible to replace current nickel-based systems in which a nickel silicide layer is formed by laser thermal annealing (LTA). Differently to the nickel silicide formation, in which carbon as by-product may be formed and the adhesion of the contact material layer is weakened, the formation of the metallic phase portion including at least a ternary component system allows the generation of Ohmic contacts with good mechanical robustness. The obtained ternary systems may not include separated or free carbon portions at the interface, thus, overcoming the problems with less adhesion of the contact on the SiC substrates. Thus, the reliability of the contacts and the robustness of the semiconductor devices produced can be improved by the methods described herein. In addition, no additional cleaning steps are necessary compared to the nickel silicide-based contacting methods, thus increasing the overall yield of the obtained products. Moreover, good Ohmic contacts between 4H—SiC substrates and contact layers of titanium, for example, can be realized without the need of dopants near the surface of the SiC substrate because of a good electrical and thermal conductivity of the ternary metallic phase generated. Generally, the methods described herein provide a large process window as will be described herein later with reference to some further embodiments and examples.

Further embodiments relate to a silicon carbide semiconductor device comprising a crystalline silicon carbide substrate, and a contact layer comprising a ternary metallic phase portion directly in contact with the silicon carbide substrate surface. The ternary metallic phase portion comprises at least a metallic contact material, silicon, and carbon, and being at least partly epitaxially grown on the crystalline silicon carbide substrate. The metallic phase portion may be obtained in line with the methods as described herein. Furthermore, the metallic phase portion may be generated at least at most parts of the interface between the contact layer and the semiconductor phase. In backside contacts, for example, a ternary phase layer may be formed at the interface. The layer may be composed of several grains of crystalline ternary metallic phase portions arranged next to each other in the form of a continuous contact layer. In addition, each of the grains may have a different crystal structure or crystal lattice orientation, for example. Therefore, the semiconductor devices obtainable by one of the methods described herein may have good and reliable Ohmic contacts due to the specific ternary metallic phase portions provided.

This disclosure, however, is not limited to the above features and advantages. Indeed, those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated examples can be combined unless they exclude each other. Examples are depicted in the drawings and are detailed in the description which follows.

FIG. 1 illustrates a silicon carbide substrate to be provided with an Ohmic contact.

FIG. 2 illustrates a silicon carbide substrate with a modified surface region.

FIG. 3 illustrates the substrate after deposition of a metallic contact material layer on its surface.

FIG. 4 illustrates the substrate after irradiation of at least a part of the carbon-enriched portion of the silicon carbide substrate and at least a part of the contact layer with a thermal annealing laser beam.

FIG. 5 illustrates an exemplary embodiment of a silicon carbide semiconductor device obtained by a method as described herein.

FIG. 6 illustrates the contact phase portion of the silicon carbide semiconductor device of FIG. 4.

FIG. 7 illustrates another embodiment of a silicon carbide substrate to be provided with an Ohmic contact.

FIG. 8 illustrates the silicon carbide substrate of FIG. 7 with a partially modified surface region.

FIG. 9 illustrates the substrate of FIG. 8 after deposition of a metallic contact material layer on its surface.

FIG. 10 illustrates the substrate of FIG. 9 after irradiation of the carbon-enriched portion of the silicon carbide substrate and at least a part of the contact layer with a thermal annealing laser beam through a protective mask layer.

FIG. 11 illustrates the substrate of FIG. 10 after removing the protective mask layer.

### DETAILED DESCRIPTION

Hereinafter, manufacturing processes for a contact on silicon carbide (SiC) substrates, which enable the production of good and reliable Ohmic contacts and offering a large process window are described in greater detail. The SiC substrates generally are silicon carbide work pieces to be processed. For example, the SiC substrate may be a SiC based wafer. The SiC substrate may, alternatively, comprise a base wafer (also called “growth substrate” or “growth wafer”) onto which semiconductor layers are deposited, e.g. by using an epitaxial process. At least one epitaxial layer may adjoin a front side of the SiC substrate. In optional process steps, a metal contact layer may be provided on the front side of the SiC substrate. In this case, the SiC substrate may be a processed wafer. Exemplary processed wafers with a SiC substrate may comprise MOFSETs, such as power MOSFETs, diodes, J-FETs, IGBTs, and so forth. Those SiC based electronic components, usually have an n-doped SiC substrate layer at the backside of the substrate to be contacted with a metallic contact layer. At the front side of the substrate, a p-doped semiconductor layer at the interface between the substrate and the metallic contact layer may be required for a reliable Ohmic contact. While emphasis is placed on manufacturing methods for Ohmic contacts at power MOSFET or diode component parts, the embodiments and examples described herein are not intended to be limited to these specific electronic components. Instead, the methods can be used for manufacturing Ohmic contacts of any other electronic components based on a SiC substrate, for example epitaxial layers comprised by the SiC substrate. Moreover, the term “substrate” may include processed wafers comprising several epitaxial layers in which the growth substrate has been removed before the backside contact may be generated. In addition, the interface between the semiconductor substrate front side and/or backside and the metal layer may be doped with dopants. For example, n-doped layers at the front side or p-doped layers at the backside may also be selected depending on the electronic device produced. For each doping type “n” or “p”, different doping concentrations can be used. Generally, these concentrations are identified as n− or p+, for example. In this specification, the doping of the substrate has not been specifically indicated, but may be implemented in each of the embodiments, if needed.

Even though the method may be used for providing the backside and front side substrate surface with Ohmic contacts, it may also be used for providing n-doped backside contacts. The terms “front side” and “backside” are used with reference to the orientation in the examples shown in the drawing section. Because components of embodiments can be positioned in a number of different orientations, the directional terminology is used for purposes of illustration only and shall in no way considered to be limiting.

The SiC substrate (and, if applicable, the epitaxial layers) provided for manufacturing the Ohmic contact thereon may, for example, be crystalline, for example monocrystalline silicon carbide substrates. Exemplary embodiments of crystalline semiconductor materials are mostly based on 4H—SiC or 6H—SiC substrates. Thus, the first step usually is providing a crystalline substrate, for example a 4H—SiC substrate. As described above, the SiC substrate may comprise device structures within the substrate. Before the steps of modifying the crystal structure, forming a contact layer and thermal annealing at least a part of the silicon carbide substrate and at least a part of the contact layer at their interface, further device structures may be produced within the base substrate, for example at the front side of the substrate. In case device structures are provided, the thermal annealing processes may be limited to temperatures not exceeding temperatures which may be harmful for the device structures. In some examples, the device structures may be protected otherwise.

In an embodiment, the modification of the crystal structure of a 4H—SiC substrate may include a separation of the 4H—SiC crystal structure, for example by breaking Si—C-bonds. The decomposition by a thermal annealing process may cause a separation into a 3C—SiC layer, a polysilicon layer, and a carbon layer. After irradiating the surface of 4H—SiC with a laser beam, a separation of phases take place. They are stacked as follows: 4H—SiC (initial substrate)/3C—SiC/Si/C. Hence, the modified surface region of the SiC substrate can be described as a carbon-enriched silicon carbide portion having a carbon-rich layer close to the surface of the SiC substrate.

In the next step, a contact layer may be formed on the carbon-enriched portion of the SiC substrate. The contact layer is composed of a metallic contact material. Exemplified contact materials may comprise at least a transition metal, e.g. titanium. Alternative transition metal materials such as Mo, Cr, V may be used as long as they are able to form a stable ternary phase with silicon and carbon by thermal annealing.

Thermal annealing may be carried out at the interface between the silicon carbide substrate surface with modified crystal structure and the contact layer. More particularly, at least a part of the carbon-enriched silicon carbide portion of the silicon carbide substrate and at least a part of the contact layer may be thermally treated by an annealing process. The temperature at the thermally treated portion may be sufficient to initiate the formation of new phases in contact with the semiconductor material. Laser-induced annealing may be used instead of using high temperatures in thermal annealing. This allows to subject wafers to thermal annealing at temperatures such that front side device structures are not affected. In some examples, the thermal annealing procedure may allow to generate a metallic phase portion at the interface which provides good Ohmic contact. In some embodiments, the contact phase portion comprises at least the metallic contact material, silicon, and carbon. During the thermal annealing, at least parts of the metallic contact material layer and at least parts of the SiC semiconductor substrate are locally heated (e.g. laser-induced) such that the crystalline structures are at least partly decomposed. During the cooling down, a reaction product comprising a metal from the metallic contact material layer, and silicon and carbon from the SiC semiconductor substrate may grow epitaxially on the silicon carbide semiconductor substrate. In some examples, the obtained metallic phase portion may be epitaxially grown without any lattice mismatch in at least parts of the metallic material layer and the SiC semiconductor substrate near the interface between these two layers. At least parts may be a portion of the layer comprising at least one or even more atomic layers or the generation of grain sections which then can again be arranged in a layer of several grains. The metallic phase portion obtained by the laser-induced thermal annealing can be described as extremely textured metallic layer over the crystalline 4H—SiC substrate. Differently to other contacting methods, no 3C—SiC layer or carbon layer may be observed if a sufficient thermal energy is applied so that a direct contact between the 4H—SiC substrate and the newly generated metallic phase portion is obtained. The substantially undisturbed crystal structure may be responsible for a relative high mobility within the 4H—SiC layer close to the interface. Thus, this highly ordered crystal structure of the semiconductor material together with a highly ordered contact phase of the metallic phase portion may be the reason for the formation of a good Ohmic contact with a high mobility close to the semiconductor to contact layer interface.

The metallic phase portion allows to offer a good Ohmic contact of the metallic contact material to silicon carbide. Unlike to the NiSi system in which carbon sometimes is expelled out to form a graphitic carbon layer on top of NiSi, there is substantially no by-product or a limited number of by-products such as carbon present in the metallic phase portion when the contact is manufactured on a silicon carbide substrate in line with the methods described herein. Therefore, the methods neither may have an adverse effect on the further processing of the substrates nor requires any post process cleaning steps. In summary, from the mechanical as well as from the electrical point of view, the metallic phase portion comprising at least a metal, carbon, and silicon features a robust system in contrast to current NiSi based systems for providing Ohmic contacts on SiC-based substrates. Generally, the methods provide large process windows as will be described herein later with reference to some further embodiments and examples.

In some embodiments of the method, the modifying of the crystal structure comprises irradiating a surface area of the silicon carbide substrate with at least one first thermal annealing laser beam. The irradiation may be carried out by one or more, for example two, three, or even more, thermal laser annealing steps. Therefore, in further embodiments, the irradiation with the first thermal annealing comprises at least two subsequent laser annealing steps. In case two or more thermal annealing steps are carried out to modify the crystal structure and generating a carbon-enriched silicon carbide portion, the laser beam irradiation may be applied in subsequent steps. Exemplified laser beam energy densities are higher than 1 J/cm² for UV laser systems with a pulse duration in the order of 150 ns, for example. The energy densities may be in the range between about 1 and about 10 J/cm² while the repetition frequency may be higher if the energy is lower (e.g. at 2 J/cm², 10 cycles may be sufficient, while at 4 J/cm², two shots are sufficient). In some examples, laser beam energy densities of higher than 3 J/cm² may be applied. Energy densities in systems with different laser incoupling properties, e.g. due to different wavelength and/or pulse duration, may be adjusted accordingly to generate a carbon-enriched layer. That is especially true for laser systems with the inherent working principle of adding multiple laser shots in a non-equilibrium phase, e.g. by applying multiple laser shots in a kHz or MHz frequency range. In this case energy density values of higher than 5 mJ/cm² are sufficient to generate a carbon-enriched layer.

In some embodiments, the modifying of the crystal structure, for example of a 4H—SiC substrate, comprises a phase separation of the silicon carbide substrate and a generation of at least a 3C—SiC polytype portion within the carbon-enriched silicon carbide portion. As explained above, the modification of the crystal structure of a 4H—SiC substrate may cause a breaking of the Si—C-bonds or at least a weakening of the crystal lattice order. The decomposition by a thermal annealing process, for example by means of an irradiation of a treatment area with a thermal annealing laser beam, may cause a separation into a 3C—SiC layer, a polysilicon layer, and a carbon layer. The thus, obtained carbon layer is close to the 3C—SiC layer and the underlying original 4H—SiC substrate. Hence, a carbon-enriched silicon carbide portion having a carbon-rich layer close to the surface of the SiC substrate is obtained and is suitably used to prepare the Ohmic contact in line with the methods described herein.

In another embodiment, the step of modifying of the crystal structure comprises implanting carbon atoms into a surface area of the silicon carbide substrate. By implanting additional carbon atoms into the surface region of a silicon carbide substrate, a carbon-enriched silicon carbide portion at or close to the surface of the silicon carbide substrate may be generated. In line with the process steps described herein, this carbon-enriched silicon carbide portion may be used to manufacture an Ohmic contact by the steps of forming a contact layer and thermal annealing at least parts of these layers at their interface in order to generate a ternary metallic phase portion as described herein before.

In some embodiments, the implantation of the carbon atoms into the surface region of the silicon carbide substrate may be carried out by a plasma deposition, standard implantation, or tilted implantation of carbon. Exemplified precursors for a plasma deposition are C₂H₂ of CF₄. In order to prepare very surface near carbon concentrations, exemplified acceleration energies in the range of about 1 to 10 keV can be used. Carbon concentrations in the range of about 3E22 cm⁻³ to 1E23 cm⁻³ can be generated within the carbon-enriched silicon carbide portion by using these plasma deposition conditions. The highest concentration of additional carbon concentrations may be prepared within the first few nanometers, for example, 2 to 20 nm, more particularly about 5 to 10 nm, close to the surface of the silicon carbide substrate treated. Alternative carbon concentration profile forms may be obtained by tuning the various parameters of the irradiation method.

In some embodiments of the method described herein, a structured protective mask layer is provided on at least one side of the crystalline silicon carbide substrate when modifying of the silicon carbide substrate and/or thermal annealing of at least a part of the contact layer. A protective mask layer, for example in the form of a hard mask, may be used if device structures are provided at the side of the crystalline substrate to be irradiated by laser pulses. In this case, the structured protective mask layer can be used to protect the heat sensitive device structures. In some examples, the structured protective mask layer may be aligned with the device structures provided in or on the surface of the semiconductor substrate. The non-protected surface area is that which shall be provided with a conductive metal structure, for example. After the modifying of the silicon substrate and/or the thermal annealing, the structured protective mask layer may be removed by suitable steps depending on the chemical or physical characteristic of the protective mask layer material. Hence, the method described herein can be used in the front-end-of-the-line processes and in low-temperature back-end-of-the-line processes. Especially, the protective mask layer may be used at the frontside of the semiconductor devices so that device structures may be protected by the structured protective mask layer.

Protective mask layer materials may be selected from coating materials which have a reflectivity and/or absorption rate of the radiation energy of the laser beam during laser thermal annealing which is higher than that of silicon carbide. In some examples, the protective mask layer, depending on the material and its thickness, may reflect or absorb at least 50%, at least 60%, or at least 70% of the radiation energy of the laser beam(s) irradiated on the surface of the silicon carbide substrate to be treated by laser thermal annealing. The material used may provide a sufficient reflectivity, or absorption rate, or reflectivity and absorption rate at the same time. The reflectivity and the absorption rate may vary depending on the thickness of the protective mask layer and the material used.

Exemplified materials for protective mask layers, for example materials having a high reflectivity, may consist of silicon oxide (e.g. SiOₓ such as SiO₂) or silicon nitride (e.g. SiₓN_{y} such as Si₃N₄) or a combination of both materials. Depending on the layer thickness of the protective mask layer or the structure of the protective mask layer (e.g., two or more layers of different materials are laminated as a stacked protective mask layer), a reflectivity of at least 50%, at least 60%, or at least 70% (e.g. in combination with a Bragg coating) can be obtained during the LTA step(s). Those results can be achieved, for example, if typical lasers having a wavelength of 308 nm are used. Alternative materials having a suitable absorption rate of laser energy, for example, may be based on Si. Some materials may have a reflectivity and absorption rate higher than silicon carbide and, thus, can suitably be used as protective mask layer materials in the processes described herein. In some examples, the protective mask layer may be a layer prepared by coating different materials in a Bragg-like configuration on the surface of the silicon carbide substrate. Thereby, the materials used in the Bragg-like coatings may have a different reflectivity while the overall reflectivity or absorption rate is higher than that of silicon carbide or of each coating material themselves.

The protective mask layer may comprise SiOₓ, SiₓN_{y}, Si, e.g., for providing absorption or absorption and reflectivity, e.g. in combination with a Bragg-like configuration. The silicon oxides or silicon nitrides or silicon can easily be structured by suitable coating processes. Well-known and optimized coating processes are available for silicon carbide substrate processing, while the chemistry of these coating processes is known, and suitable thicknesses or thickness variations can be adjusted by known processes.

The use of a protective mask layer, thus, allows to avoid or lower the risk of degradation of frontside device structures (apart from 4H—SiC), for example structures prepared at the SiO₂/4H—SiC or SiO₂/poly-Si interfaces, when irradiating the side of the crystalline silicon carbide substrate with laser pulses. The device structures are shielded or protected by the protective mask layer, while the ternary metallic phase can be generated in those regions not protected by the reflective mask layer. The regions with a ternary metallic phase as described herein provide contact areas with an improved contact resistance behavior.

Further described herein is the use of protective mask layers, e.g. reflective mask layers and/or absorption layers, for reducing or eliminating the effect of laser in-coupling into specific regions of the device, especially, into regions with device structures or heat-sensitive structures, for example, at the frontside of a semiconductor device at which contact areas shall be formed. Backside contacts may be realized analogously with the use of reflective mask layers in line with the embodiments described herein.

In some embodiments, the regions to be treated and being not protected by a protective mask layer can additionally be provided with an anti-reflective coating. Using such anti-reflective coatings may result in regions having a good contact resistance while lowering the energy of the laser pulses needed for the generation of the ternary metallic phase. Anti-reflective coatings in general lower the amount of reflection of the laser pulses at their surface. Thus, higher energy levels can be measured in the area below these anti-reflective coatings. Thus, a combination of protective masks layers, e.g. reflective mask layers and/or absorbing layers, and anti-reflective coatings may be used to improve a method of preparing semiconductor devices with high contact resistance at selected regions while laser in-coupling into regions not intended to be modified can be reduced or eliminated at the same time.

The above-described methods using a protective mask layer may be used in double LTA processes, but also in methods for manufacturing a contact on a silicon carbide semiconductor substrate by depositing a metallic contact material layer onto a silicon carbide substrate and irradiating at least a part of the silicon carbide substrate and at least a part of the metallic contact material layer. The energy of the irradiated laser pulses may decompose the silicon carbide substrate by melting processes. After the cooling down of the melted silicon carbide substrate areas, a contact phase portion may be generated at the interface between the silicon carbide material and the contact material. The cooled material may comprise a ternary phase as described herein before, which may consist of grains of crystallites comprising a three-phase system of at least a metal, silicon, and carbon, sometimes also called MAX phase. The use of the protective mask layer in a structured form may allow the use of this method for the production of good contacts at the backside, but also at the frontside of a silicon carbide semiconductor product, for example.

According to some embodiments, the contact layer deposited on the obtained carbon-enriched silicon carbide substrate surface is based on a metallic component as contact material. Exemplified metallic components for the contact layer comprises a metal, metal silicide, metal carbide, or ternary silicide and carbide of a metal. In some examples, the metal may be a transition metal. The transition metal may be selected of the group of titanium (Ti), molybdenum (Mo), zirconium (Zr), niobium (Nb), hafnium (Hf), tantalum (Ta), vanadium (V), chromium (Cr), and tungsten (W). All of these may generate stable ternary phases with silicon and carbon having chemical and physical properties which may be suitable for establishing good contact materials for SiC-based semiconductor devices. In some embodiments, the metallic contact material comprises at least titanium.

In an embodiment, the contact layer material may comprise a mixture of titanium, carbon, and silicon, for example in a stoichiometry equal or similar to Ti₃SiC₂. The sputtering of this mixed material onto the semiconductor substrate prepared as described before may be used for front side Ohmic contacts, for example. Similar effects can be obtained when being used for the preparation of backside contacts. After the sputtering of the mixed material onto the substrate, an LTA pulse with an energy density which provides heat high enough to create a near-epitaxial re-arrangement of Ti₃SiC₂ may be applied. The LTA process initiates the generation of a highly ordered ternary phase (e.g. MAX phase) which consumes the previously formed carbon and silicon, thus, eliminating all causes for metal delamination and providing a metallic phase portion onto the high-mobility 4H—SiC layer. The thus produced Ohmic contacts may reduce the source doping level without deteriorating the contact resistance. Therefore, it may improve the semiconductor devices produced by this method for short-circuit ruggedness. Ti₃SiC₂ has very good electrical and thermal conductivity, thus enabling a good heat spreading for the case of current filamentation. Moreover, the mixed titanium silicon carbon phases have a very high melting temperature, allowing the manufacture of semiconductor devices with good and robust Ohmic contacts.

According to an embodiment, the thermal annealing of the interface between the carbon-enriched silicon carbide substrate and the contact layer is carried out with at least one second thermal annealing laser beam. In systems with titanium as metallic contact material, for example, in a thickness of about 20 to 40 nm, exemplified thermal annealing procedures may comprise the use of laser beams having an energy of at least 4.0 J/cm². The energy density required for the ternary phase formation may be reduced by increasing the content of implemented carbon. Therefore, the additional carbon implantation may facilitate the growth of the ternary phase and reduction of the contact resistance. Higher thicknesses of the metal layer may need higher energy regimens in order to form grains of crystallites comprising titanium, silicon, and carbon. In case two or more subsequent laser pulses are applied at the same location, lower energy densities, for example, 3.8 J/cm² or more, more particularly, 3.9 J/cm² or more, for example about 4.0 J/cm², may be sufficient to form the crystallites. In case other metals are used as contact material, different energy densities and thicknesses may be applied. In order to produce an Ohmic contact at least part of the crystallites shall grow in an epitaxial manner on the silicon carbide semiconductor substrate near the interface of the metallic contact material layer and the semiconductor substrate.

In another embodiment, the thermal annealing of at least a part of the carbon-enriched silicon carbide portion and at least a part of the contact layer comprises melting of at least parts of the carbon-enriched silicon carbide portion and parts of the contact material and epitaxially reorganizing the obtained ternary metallic phase portion. Thereby laser thermal annealing procedures as described before can be used as single laser beam irradiation or subsequent irradiation with two or even more independent laser beams. According to some embodiments, the irradiation with at least one thermal annealing laser beam is adjusted to melt the metallic contact layer and enable diffusion of metal atoms within the silicon carbide semiconductor substrate at least partially at the interface of the silicon carbide semiconductor substrate and the metallic contact material layer. At least one may mean the application of two or more independently applied laser beams at the same location. A timely overlap of the application of the two or more laser beams may be possible. In some embodiments, the two or more laser beams may be applied in sequence with a cooling down of the generated mixed phase at the location of irradiation. Upon irradiation with the at least one laser beam, the metal material reacts with the silicon carbide. Thereby the constituent elements of the semiconductor substrate, that means, silicon and carbon, are consumed by the reaction melt forming a ternary phase of metal, silicon, and carbon. By-products as sometimes obtained by laser thermal annealing of silicon carbide semiconductor substrates may not be generated in this process due to the formation of the ternary phase with the metallic material component. The formation of the ternary phase may be described as a diffusion process of metal atoms within the melted silicon carbide semiconductor substrate components. Melted may mean a decomposition of the silicon carbide crystal structure and silicon carbon bonds, thus enabling the forming of a new crystalline phase, the so-called ternary phase.

The applied energy of the second thermal annealing procedure is adjusted such that a ternary metallic phase portion is obtained which comprises a ternary phase of a metal, silicon, and carbon. Ternary phase may be any three-component phase system including crystalline, such as monocrystalline or polycrystalline, phases comprising a metal, silicon, and carbon, wherein the metal is based on the metallic contact material deposited on the semiconductor substrate.

In some embodiments, the metallic phase portion at the interface may be a crystalline phase mixed of two components of the three-component system while the third component is intercalated. In some embodiments, it may be a crystalline phase comprising all three components. The stoichiometry as well as the crystal structure highly depend on the content of each of the three components present in the ternary phase.

In some embodiments, the metallic phase portion at the interface may comprise grains, wherein at least a part of these grains may comprise a hexagonal crystal structure. More particularly, not all grains are grown strictly epitaxially as they may be, for example, not a continuous crystal. For example, the grains may be discontinuous hexagonal grains of different orientation, which might contain non-hexagonal structures. However, at least a part of the grains is epitaxially grown on the semiconductor substrate as the ternary phase may have the same or comparable lattice parameters as the crystalline SiC semiconductor substrate material. Exemplified ternary phases having a hexagonal crystal structure may be characterized as Mₙ₊₁AXₙ phases (also called MAX phases), wherein M is a metal or early transition metal, A is a metalloide (e.g. element from groups 12-16), for example silicon, and X is carbon or nitrogen. Examples of such MAX phases having similar lattice parameters than hexagonal SiC are Ti₃SiC₂, Ti₂SiC, or Mo₃SiC₂. In case of titanium as metal contact component, the ternary metallic phase portion may comprise TixSiyCz, wherein x=2.8−3.2, y=1, z=1.8−2.2.

In some embodiments, the obtained metallic phase portion comprises layers of transition metal carbide with intercalated layers of silicon similar to so-called MAX phases described in the literature as materials with special chemical and physical properties. In some examples, however, the metallic phase portion may deviate from the exact stoichiometry as described for these MAX phases and may have a different content, for example, a higher content, of silicon in some grains obtained by irradiation with sufficient energy density. In some examples, the grains mainly consist of a ternary phase in which no transition metal carbide crystalline structure can be observed in the EDX (elemental analysis) or XRD measurements. The grains or the ternary phase layer close to the interface may contain the lowest silicon concentration while the grains in the layers extending more into the metallic contact material layer may have a higher content of silicon in the ternary phase. Thus, MAX phases of different order may be contained within the contact phase portion. In exemplified MAX phases you can find a different number of stacked or layered transition metal carbide crystal units. For example, a stack of one or two or three such crystal units may be generated before one Si layer is intercalated, thus forming the ternary phase. Thus, depending on the number of stacks of crystal units, the silicon content varies in such ternary phases of the metallic phase portions. In some examples, the crystal units may be seen as being embedded in a Si matrix in different contents so that Si-poor or Si-rich ternary phases of the metallic phase portions may be generated. In some examples, the layer of grains or the continuous ternary phase layer comprises a titanium transition metal carbide crystal structure intercalated with about 0 to 25% silicon, more particularly, about 5 to 15% silicon, in particular, about 5 to 7% silicon.

The methods as described before may be used to prepare silicon carbide semiconductor devices. Accordingly, the silicon carbide semiconductor devices obtainable or obtained with these methods may fall within the herein described products. Some embodiments of silicon carbide semiconductor devices comprise a crystalline silicon carbide substrate, and a contact layer comprising a ternary metallic phase portion directly in contact with the silicon carbide substrate surface, wherein the ternary metallic phase portion comprises at least a metallic contact material, silicon, and carbon. According to some embodiments, the ternary metallic phase portion may be at least partly epitaxially grown on the crystalline silicon carbide substrate. In these semiconductor devices, good Ohmic contacts may be realized due to the presence of an improved metallic phase portion as described herein. The metallic phase comprises at least a metallic contact material, silicon, and carbon in admixture, more particularly, in a crystalline form providing a good Ohmic contact at the interface between the semiconductor substrate surface and the metallic contact material layer.

In some embodiments, the metallic contact phase portion at an interface to the silicon carbide semiconductor substrate comprises grains, wherein at least a part of these grains comprises a hexagonal crystal structure. The hexagonal crystal structure may be grown in an epitaxial manner on the semiconductor substrate surface in at least parts of the interface, thereby improving the Ohmic contact at least at these portions. In some examples, the whole substrate surface is provided with an Ohmic contact due to the highly ordered crystal structure of the metallic phase at the interface. Hence, the highly ordered metallic phase portion may provide a good Ohmic contact with the 4H—SiC substrate having a high mobility. Compared to contacts based on 3C—SiC intermediate layers, the 4H—SiC semiconductor material provides an improved mobility of the charge carriers due to a higher mobility of the free charge carriers, thus reducing the contact resistance significantly. Local 3C—SiC regions within the 4H—SiC layer arrangements are possible, too.

In some embodiments, the silicon carbide semiconductor device may comprise at least one further metal layer deposited above the contact layer. This allows to improve the contact and bonding properties of the finished semiconductor device to other device structures in finished products. In some embodiments, the contact layer is provided as backside contact. In further embodiments, the semiconductor substrate may comprise several device structures at the front side surface before the Ohmic contact at the rear side may be manufactured.

The manufacturing methods described herein allow the production of Ohmic contacts in an efficient manner offering a large process window. As substantially no precipitation of by-products is observed during the manufacturing of the Ohmic contacts, post-processes cleaning steps may not be needed. This increases the overall yield. At the same time, the obtained semiconductor devices offer good mechanical robustness, high reliability, and high mobility of the charge carriers. The thus obtained SiC based semiconductor devices are produced with good and homogeneous Ohmic contacts, especially at the backside of the semiconductor substrate. Due to the specific ternary phase in the metallic phase portion, the Ohmic contact resistance may be lower than in current nickel silicide-based or 3C—SiC-based systems, thus reducing the electrical resistance of the semiconductor devices obtainable by the methods described herein. The very good contact resistance at the interface contribute to a reduction of the on-state losses of SiC based semiconductor devices such as MOSFETs, diodes, J-FETs, IGBTs, and so forth.

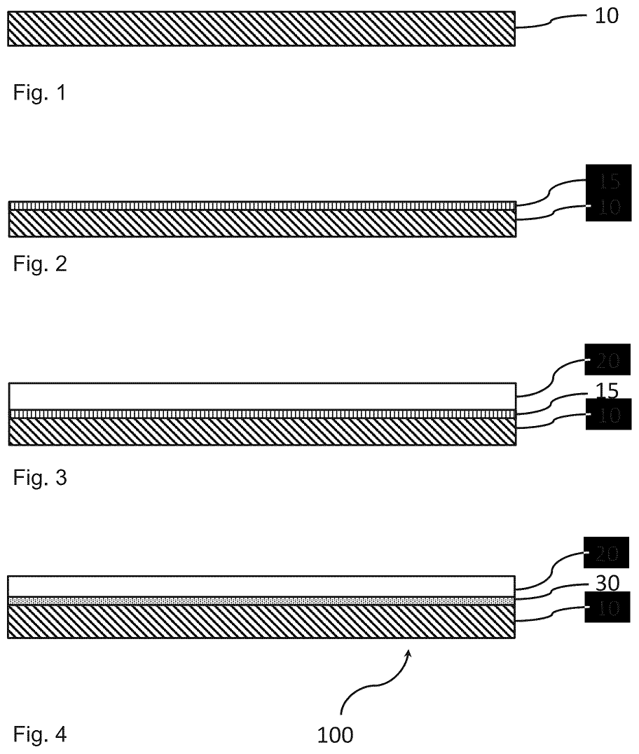

The above-described embodiments will be further described by referring to the drawings which show specific examples of the methods and semiconductor devices obtained therewith. Referring now to FIGS. 1 to 4, a method of manufacturing an exemplary embodiment of a semiconductor device has been shown. FIG. 1 illustrates a cross-sectional view of a SiC substrate to be provided with an Ohmic contact. The monocrystalline SiC substrate layer 10 may, for example, mainly comprise a 4H—SiC wafer material. As a preparatory step, the wafer may be prepared by a typical thinning technique to provide a polished surface of SiC.

Now referring to FIG. 2, in a further step of the herein described exemplified method, a plasma deposition of carbon into the SiC substrate backside has been performed utilizing a precursor, for example C₂H₂ or CF₄. The acceleration energies were in the range of 1-10 keV. The obtained high carbon concentrations of about 3E22 cm⁻³ to 1E23 cm⁻³ could be detected in a concentration profile with its maximum at a position very near to the SiC substrate surface. Most of the carbon atoms were implanted in regions with a distance to the surface of about 5-10 nm. The total thickness of the carbon-enriched SiC portion 15 is about 50 nm, more particularly, about 40 nm, for example about 30 nm.

The carbon-enriched SiC substrate portion 15 may also be generated by a first laser thermal annealing with at least one laser beam, thus generating a 3C—SiC layer, a polysilicon, layer, and a carbon layer, stacked in this order above the SiC substrate 10.

In the next step, a contact layer 20 is deposited on the carbon-enriched SiC portion 15 of the SiC substrate 10 as it is shown in FIG. 3. For example, a titanium layer may be deposited by a sputtering or chemical vapor deposition technique in a thickness of about 40 nm. Alternative thickness levels may be between about 20 and 150 nm, more particularly, about 20 nm or about 40 nm or about 100 nm.

The metallized SiC substrate surface, that means the interface between the carbon-enriched portion 15 of the SiC substrate and the contact layer 20 deposited thereon, is subjected to laser thermal annealing. The irradiation of at least a part of the carbon-enriched SiC substrate 15 and at least a part of the contact layer 20 may be carried out by irradiation with an annealing laser beam to generate a reaction between the titanium as metallic material and SiC of the semiconductor substrate. The constituents of the semiconductor substrate, namely Si and C, are consumed by this reaction under high temperature and create a layer comprising a ternary phase of titanium, silicon, and carbon, the metallic phase portion 30. It was observed that substantially no by-product such as free carbon clusters are generated. Moreover, in case a 3C—SiC layer has been formed in the first thermal annealing step, also this layer may have been recrystallized if sufficient energy density of the laser beams has been applied. The direct contact of the ternary metallic phase 30 to the 4H—SiC substrate enables a high mobility of charge carries, thus, enabling good Ohmic contacts. A SiC semiconductor device 100 prepared accordingly, is shown in FIG. 4. Most of the metallic phase portion 30 is composed of the ternary phase comprising at least three components, namely titanium, silicon, and carbon. In some examples, especially, if mixed metallic contact materials are used, a fourth component or additional components may be present in the contact phase portion, thereby forming a mixed phase of four or more components instead of a ternary phase.

In order to generate temperatures high enough to decompose the SiC crystalline structure and form the ternary system with the titanium, the energy density of the laser beam is adjusted accordingly. In some examples, two or more laser pulses may be applied to achieve the melting of the crystal structure and the formation of the ternary phase. Especially, in the system of titanium as metal contact material, 4.0 J/cm² or higher may be sufficient to form Ohmic contacts between the SiC substrate 10 and the deposited titanium contact layer 20 in one laser thermal annealing step. It has been observed that higher contents of carbon in the carbon-enriched portion 15 may result in good Ohmic contacts by reducing the energy density to be applied in the laser thermal annealing step. Using two laser thermal annealing steps or two subsequent laser beam irradiations, the energy density of each laser beam may be reduced. For example, two times 3.8 or 4.0 J/cm² may be sufficient to obtain a similar or improved Ohmic contact compared to a single laser thermal annealing step with about 4.0 J/cm².

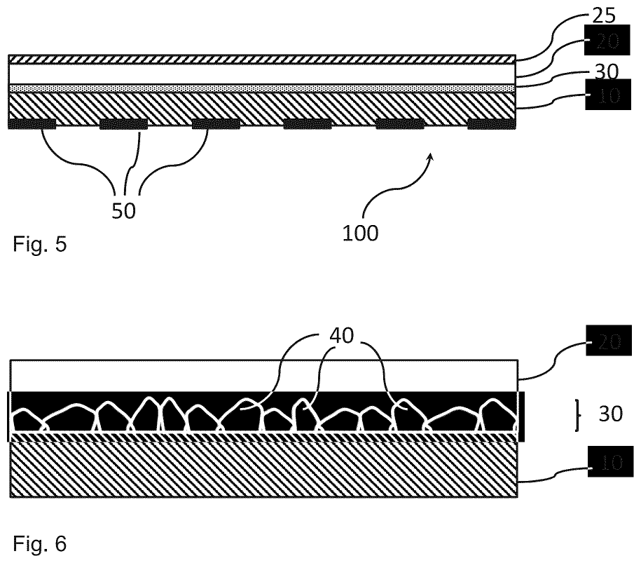

FIG. 5 illustrates an exemplary embodiment of a silicon carbide semiconductor device 100 obtained by a method as described herein. The crystalline SiC substrate 10 may be provided at its front side surface with several device structures 50 previously prepared before a thinning step may be carried out at its rear side. The SiC semiconductor device 100 further comprises a metallic phase portion 30, a contact layer 20, and a further metal layer 25 deposited on the backside of the crystalline SiC substrate layer 10. Using a method as described herein, it is possible to produce a good Ohmic contact at the backside of a crystalline SiC semiconductor substrate without heating the whole wafer. Thus, already prepared device structures 50 likely are not damaged due to excessive heat. As the generation of the ternary metallic phase portion at or near the interface to the SiC substrate interface is carried out at sufficiently high energy densities, the growth of the ternary TiSiC phase takes place in an epitaxial manner, adopting the lattice parameters of the SiC substrate at least in some parts of the contact phase portion. Thus, the formation of a good Ohmic contact is obtained, even though the contact phase portion does not necessarily match with the Ti₃SiC₂ stoichiometry for a typical MAX phase. Assumingly, the match of the grown crystallites in the contact phase portion significantly reduces the contact resistance to the SiC semiconductor substrate. At the same time, the contact provides a good mechanical robustness and a high reliability.

FIG. 6 illustrates the metallic phase portion of the silicon carbide semiconductor device of FIG. 5. In the metallic phase portion 30, at least one layer of grains 40 is formed by the irradiation with at least one laser beam with sufficient energy density. Each grain is composed of a ternary TiSiC phase. At least some of the grains 40 at the interface to the SiC substrate 10 comprises a crystalline hexagonal structure. In some examples, most of the grains 40 have a hexagonal crystal structure, thus decreasing the contact resistivity and providing good Ohmic contact. In further examples, at least a part of these grains 40 is epitaxially oriented to the crystal lattice of the crystalline SiC substrate 10 to further decrease the contact resistance at the interface of the SiC substrate 10 and the contact layer 20. The layer of grains is shown in this Figure only schematically. It may comprise grains with different sizes, holes filled with silicon or TiSiC matrix material. It may also comprise stacked layers of several grain layers.

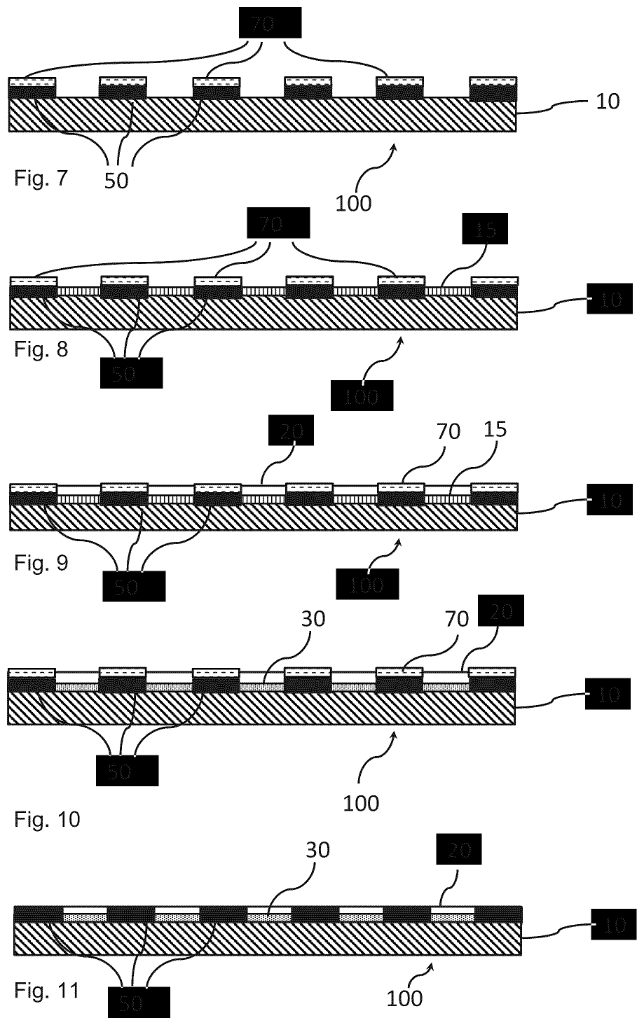

Referring now to FIGS. 7 to 11, an alternative method of manufacturing an exemplary embodiment of a semiconductor device has been shown. FIG. 7 illustrates a cross-sectional view of a SiC substrate to be provided with an Ohmic contact. The monocrystalline SiC substrate layer 10 as described with regard to the embodiment in FIG. 1, for example, mainly comprise a 4H—SiC wafer material. Any features described with the embodiment shown in FIGS. 1 to 4 can be embodied in this embodiment as well even though it is not repeated here again. In this alternative embodiment, the SiC substrate has at one side thereof several device structures 50 near or at the surface of the substrate. The device structures 50 may be heat-sensitive and, thus, may not be directly irradiated with laser pulses during the LTA processing to avoid degeneration by the heat. In order to protect them during the consecutive process steps, a structured protective mask layer 70 is provided on the SiC substrate. The protective mask layer 70 may be generated at those regions of the SiC substrate 10 to be protected from LTA laser pulses.

Now referring to FIG. 8, in a further step of the herein described exemplified method, a plasma deposition of carbon into the SiC substrate 10 has been performed to increase the carbon concentration near the surface where the contact regions shall be provided. The carbon-enriched SiC substrate portion 15 may also be generated by a first laser thermal annealing with at least one laser beam, thus generating a 3C—SiC layer, a polysilicon, layer, and a carbon layer, stacked in this order above the SiC substrate 10. The protective mask layer 70 reduces or eliminates the effect of the laser pulses below the mask, that means at regions where device structures 50 are provided at the frontside of the SiC substrate 10. In this embodiment, a reflective mask layer comprising silicon oxide may be used. Alternatively, reflective mask layers of different materials (e.g. silicon oxide and silicon nitride) may be provided as thin coatings in a Bragg-like laminate structure of more than two different consecutive layers, for example. In addition, or alternatively, a silicon layer as absorption layer may be used in the protective mask layer.

In the next step, a contact layer 20 is deposited on the carbon-enriched SiC portion 15 of the SiC substrate 10 as it is shown in FIG. 9. Thereby, the contact layer 20 is provided at those regions which shall be used for metal contact in the finished product, but not above the device structures 50. For example, a titanium layer may be deposited by a sputtering or chemical vapor deposition technique in a thickness of about 40 nm. Alternative thickness levels may be between about 20 and 150 nm, more particularly, about 20 nm or about 40 nm or about 100 nm.

The metallized SiC substrate surface, that means the interface between the carbon-enriched portion 15 of the SiC substrate and the contact layer 20 deposited thereon, is subjected to laser thermal annealing. The irradiation of at least a part of the carbon-enriched SiC substrate 15 and at least a part of the contact layer 20 may be carried out by irradiation with an annealing laser beam to generate a reaction between the titanium as metallic material and SiC of the semiconductor substrate. The constituents of the semiconductor substrate, namely Si and C, are consumed by this reaction under high temperature and create a layer comprising a ternary phase of titanium, silicon, and carbon, the metallic phase portion 30 as it has been described with the embodiment in FIGS. 1 to 4. As it is shown in FIG. 10, the protective mask layer 70 is used to reduce or eliminate the direct irradiation of the device structures 50 by the laser pulses, thus, protecting them from heat degeneration.

In some examples, a non-reflective coating (not shown in the Figures) may be coated on those parts of the substrate surface to be treated. A non-reflective coating may increase the energy at parts of the substrate to be converted into a ternary phase while neighboring regions of the substrate to be treated, especially, regions protected by the protective mask layer 70 and containing device structures 50, may not heated in a substantial manner. The use of an anti-reflective coating in addition to the protective mask layers 70 described herein may improve the reliability of the obtained semiconductor device 100.

After the (second) thermal annealing, the protective mask layer 70 may be removed by suitable mechanical or chemical processes, such as etch processes. The use of the protective mask layer 70 results in a SiC semiconductor device 100, which is shown in FIG. 11. Most of the metallic phase portion 30 is composed of the ternary phase comprising at least three components, namely titanium, silicon, and carbon. In some examples, especially, if mixed metallic contact materials are used, a fourth component or additional components may be present in the contact phase portion, thereby forming a mixed phase of four or more components instead of a ternary phase. In those regions where no metallic contact regions are prepared, device structures 50 may be present. Therefore, this embodiment can suitably be used also for frontside contact processes. Generally, protective mask layers may be used in preparation methods of backside and/or frontside contacts, either without or with one or more LTA processes.

The above illustrated manufacturing method of a contact on a monocrystalline SiC substrate allows the fabrication of a reliable Ohmic contact within a broad process window. Hence, the overall manufacturing process is easier and results in good and reliable Ohmic contacts and an improved robustness of the obtained SiC semiconductor devices.

Terms such as “first”, “second”, and the like, are used to describe various embodiments, layer, order of steps, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments and examples shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A method for manufacturing a contact on a silicon carbide substrate, the method comprising:
providing a crystalline silicon carbide substrate;
modifying a crystal structure in a surface area of the crystalline silicon carbide substrate such that a carbon-enriched silicon carbide portion is generated in the surface area;
forming a contact layer on the crystalline silicon carbide substrate by depositing a metallic contact material onto the surface area comprising the carbon-enriched silicon carbide portion; and
thermal annealing at least a part of the carbon-enriched silicon carbide portion of the crystalline silicon carbide substrate and at least a part of the contact layer, such that a ternary metallic phase portion comprising at least the metallic contact material, silicon, and carbon is generated.

2. The method of claim 1, wherein the modifying comprises irradiating a surface area of the crystalline silicon carbide substrate with at least one first thermal annealing laser beam.

3. The method of claim 2, wherein the irradiating comprises at least two subsequent laser annealing steps.

4. The method of claim 1, wherein the modifying comprises a phase separation of the crystalline silicon carbide substrate and a generation of at least a 3C—SiC polytype portion within the carbon-enriched silicon carbide portion.

5. The method of claim 1, wherein the modifying comprises implanting carbon atoms into a surface area of the crystalline silicon carbide substrate such that the carbon-enriched silicon carbide portion is generated at or close to the surface of the crystalline silicon carbide substrate.

6. The method of claim 5, wherein implanting comprises a plasma deposition, standard implantation, or tilted implantation of carbon.

7. The method of claim 5, wherein the carbon concentration within the carbon-enriched silicon carbide portion is in a range of 3E22 cm⁻³ to 1E23 cm⁻³.

8. The method of claim 1, wherein a structured protective mask layer is provided on at least one side of the crystalline silicon carbide substrate when modifying the crystalline silicon carbide substrate and/or thermal annealing of at least a part of the contact layer, and wherein the protective mask layer has a reflectivity and/or absorption rate of radiation energy of a laser beam during laser thermal annealing higher than that of silicon carbide.

9. The method of claim 1, wherein thermal annealing of an interface between the carbon-enriched silicon carbide portion and the contact layer is carried out with at least one second thermal annealing laser beam.

10. The method of claim 1, wherein the thermal annealing comprises:
melting at least parts of the carbon-enriched silicon carbide portion and parts of the metallic contact material; and
epitaxially reorganizing a ternary metallic phase portion obtained by the melting.

11. The method of claim 1, wherein the metallic contact material comprises at least titanium.

12. The method of claim 11, wherein the ternary metallic phase portion comprises TiₓSi_{y}C_{z}, and wherein x=2.8-3.2, y=1, z=1.8-2.2.

13. A silicon carbide semiconductor device, comprising
a crystalline silicon carbide substrate; and
a contact layer comprising a ternary metallic phase portion directly in contact with a surface of the crystalline silicon carbide substrate,
wherein the ternary metallic phase portion comprises at least a metallic contact material, silicon, and carbon, and is at least partly epitaxially grown on the crystalline silicon carbide substrate.

14. The silicon carbide semiconductor device of claim 13, wherein the ternary metallic phase portion comprises at least one layer of grains at an interface to the crystalline silicon carbide substrate.

15. The silicon carbide semiconductor device of claim 13, further comprising at least one further metal layer deposited above the contact layer.

16. The silicon carbide semiconductor device of claim 13, wherein the contact layer forms a backside contact of the silicon carbide semiconductor device.

17. The silicon carbide semiconductor device of claim 16, wherein the crystalline silicon carbide substrate comprises a plurality of device structures at a frontside surface.
